(19) United States
(12) Patent Application Publication
(10) Pub. No.: US 2026/0047214 A1
(43) Pub. Date: Feb. 12, 2026

(54) SINGLE-PHOTON AVALANCHE DIODE (SPAD) SENSOR, SEMICONDUCTOR STRUCTURE INCLUDING SPAD SENSOR, AND METHOD FOR FORMING THE SAME

(71) Applicant: TAIWAN SEMICONDUCTOR MANUFACTURING COMPANY LTD., HSINCHU (TW)

(72) Inventors: TZU JUNG TIEN, HSINCHU COUNTY (TW); CHEUNG CHENG, HSINCHU CITY (TW)

(21) Appl. No.: 18/795,221

(22) Filed: Aug. 6, 2024

(51) Int. Cl. H01L 31/107; H01L 27/144

(52) U.S. Cl. CPC H10F 30/225; H10F 39/107

(57) ABSTRACT

A semiconductor structure includes a first well in a semiconductor substrate, a plurality of fin-like doped regions over and coupled to the first well in the semiconductor substrate, and a second well over the first well and the plurality of fin-like doped regions in the semiconductor substrate. The first well and the plurality of fin-like doped regions comprise a first conductivity type, and the second well comprises a second conductivity type complementary to the first conductivity type. A first interface is formed between the second well and the first well, a second interface is formed between the second well and the plurality of fin-like doped regions, and each of the first interface and the second interface has a non-planar configuration.

### BACKGROUND

A single-photon avalanche diode (SPAD) sensor is able to detect incident light at very low intensities, including single photon detection. A SPAD is a photodiode including a p-n junction that operates at a reverse bias above a breakdown voltage. During operation, photo-generated carriers move to a depletion region (i.e., a multiplication junction region) of the p-n junction and trigger an avalanche effect such that a signal current is detected with high timing accuracy. Further, the avalanche is quickly quenched to prevent damage to the p-n junction. The p-n junction is then reactivated by recharging the junction to a voltage greater than the breakdown voltage.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a flowchart representing a method for forming a SPAD sensor in accordance with aspects of the present disclosure.

FIGS. 2 to 9B are schematic drawings showing various stages in a formation of a SPAD sensor in accordance with aspects of the present disclosure in one or more embodiments, wherein FIGS. 8A and 8B and FIGS. 9A and 9B show various embodiments of stages in the formation of the SPAD sensor.

FIG. 10A is a plan view of the semiconductor substrate after formation of a plurality of fin-like structures and a mesa; and FIG. 10B is a cross-sectional view taken along a line I-I′ of FIG. 10A.

FIG. 11A is a plan view of the semiconductor substrate after formation of a plurality of fin-like structures and a mesa; and FIG. 11B is a cross-sectional view taken along a line II-II′ of FIG. 11A.

FIG. 12A is a plan view of the semiconductor substrate after formation of a plurality of fin-like structures and a mesa, and FIG. 12B is a cross-sectional view taken along a line III-III′ of FIG. 12A.

FIG. 13 is a flowchart representing a method for forming a semiconductor structure including a SPAD sensor in accordance with aspects of the present disclosure.

FIGS. 14 to 24B are schematic drawings showing various stages in a formation of a semiconductor structure including a SPAD sensor in accordance with aspects of the present disclosure in one or more embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature on or over a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of brevity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

The present disclosure provides a SPAD sensor having a plurality of fin-like p-n junctions. In some embodiments, the fin-like p-n junctions, which are formed by dopings, have a wavy or non-planar configuration. Accordingly, an area of the fin-like p-n junction is increased. As a result, a quantity of photo-generated carriers generated in the fin-like p-n junction per unit area is increased compared to a quantity of photo-generated carriers in a comparative SPAD sensor having the p-n junction formed in a planar surface. Accordingly, efficiency of the SPAD sensor is improved, and resolution for application of machine vision is improved.

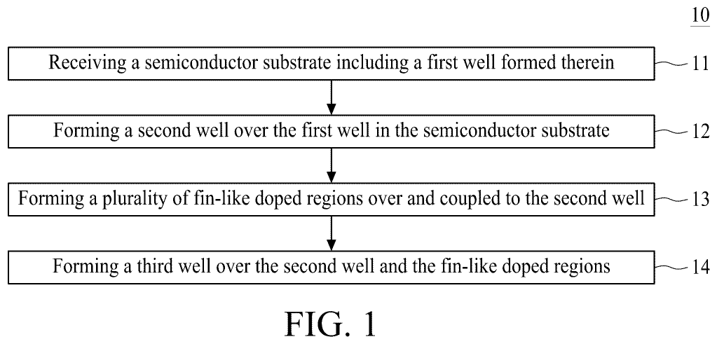

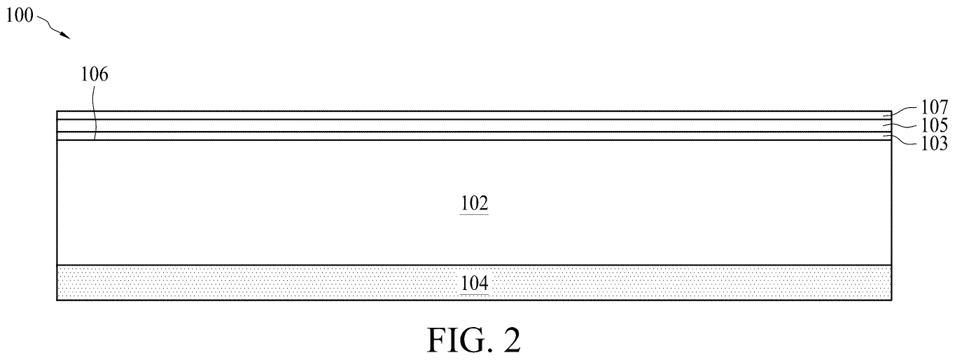

FIG. 1 is a flowchart representing a method for forming a SPAD sensor 10 in accordance with aspects of the present disclosure. Persons having ordinary skill in the art will understand that, in some embodiments, additional operations may be performed before, during or after the method 10, and that some of the operations described may be replaced or eliminated in some embodiments of the method 10. FIGS. 2 to 9B are schematic drawings illustrating the method 10 of forming the SPAD sensor at various fabrication stages in accordance with some embodiments of the present disclosure.

In some embodiments, the SPAD sensors may be formed for front side illumination (FSI), meaning that the SPAD sensors are arranged to be photosensitive to light incident on a front surface of a substrate. For an image sensor including the SPAD sensors arranged for FSI, a majority of photon absorption occurs near the front surface of the substrate. In some alternative embodiments, the SPAD sensors are formed for back side illumination (BSI), meaning that the SPAD sensors are arranged to be photosensitive to light incident on a back surface of a substrate. For an image sensor including the SPAD sensors arranged for BSI, a majority of photon absorption occurs near the back surface of the substrate.

The method for forming the SPAD sensor 10 provided by the present disclosure can be performed to form the SPAD sensor for FSI or BSI. Further, the method for forming the SPAD sensor 10 can be integrated with planar device formation, or with non-planar device formation such as FinFET device formation and gate-all-around (GAA) device formation.

Referring to FIGS. 1 and 2, in some embodiments, the method 10 includes an operation 11, in which a semiconductor substrate 102 including a well 104 formed therein is received. In some embodiments, the semiconductor substrate 102 may include any type of semiconductor body, such as a substrate formed of silicon, a material including silicon, a III-V compound semiconductor material such as silicon germanium (SiGe) or gallium arsenide (GaS), or a silicon-on-insulator (SOI), but the disclosure is not limited thereto. As shown in FIG. 2, the well 104 is formed in the semiconductor substrate 102 and separated from a surface 106 of the semiconductor substrate 102. In some embodiments, the well 104 may include dopants of a first conductivity type, for example, an n-type dopants. In such embodiments, the well 104 may be referred to as a deep n well (DNW). In some embodiments, an epitaxial layer may be formed over the well 104 to separate the well 104 from the surface 106 of the semiconductor substrate 102.

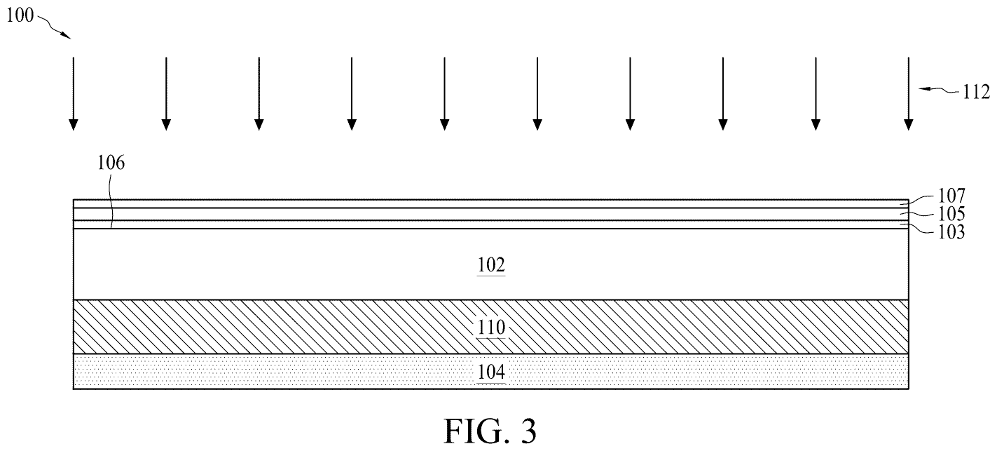

Referring to FIGS. 1 and 3, in some embodiments, the method 10 includes an operation 12, in which a well 110 is formed over the well 104 in the semiconductor substrate 102. In some embodiments, a pad oxide layer 103 may be formed prior to or after the forming of the well 110. In some embodiments, a hard mask layer 105 may be formed over the pad oxide layer 103, and an anti-reflective coating (ARC) 107 may be formed over the hard mask layer 105. In some embodiments, the forming of the well 110 includes a doping of the semiconductor substrate 102 through the ARC 107, the hard mask layer 105 and the pad oxide 103. In some embodiments, the doping includes an ion implantation 112. In such embodiments, an implant energy of the ion implantation 112 may be between approximately 60 keV and approximately 2500 keV, but the disclosure is not limited thereto.

In some embodiments, the well 104 and the well 110 include a same conductivity type, for example, the n type. In some embodiments, the well 104 is referred to as the DNW, and the well 110 is referred to as a portion of a SPAD N-well. Further, a doping concentration of the well 110 is greater than a doping concentration of the well 104. As shown in FIG. 3, the well 110 is formed over and coupled to the well 104. In some embodiments, a bottom of the well 110 is in contact with the well 104, but the disclosure is not limited thereto. In some embodiments, a top of the well 110 is still separated from the surface 106 of the semiconductor substrate 102.

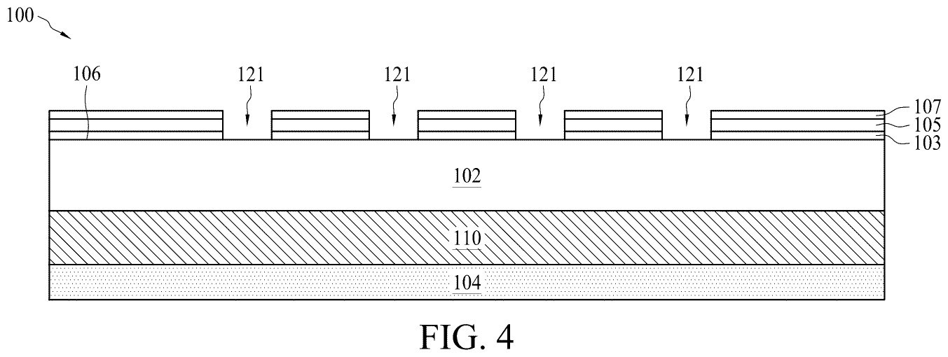

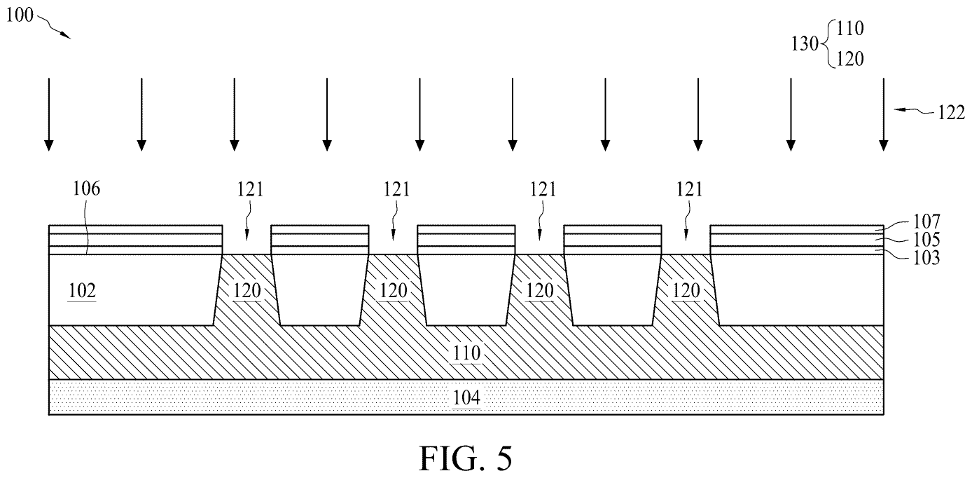

Referring to FIGS. 1, 4 and 5, in some embodiments, the method 10 includes an operation 13, in which a plurality of fin-like doped regions 120 are formed in the semiconductor substrate 102. Further, the fin-like doped regions 120 are formed over and coupled to the well 110. As shown in FIG. 4, in some embodiments, the forming of the fin-like doped regions 120 includes patterning the ARC 107, the hard mask layer 105 and the pad oxide layer 103 with suitable photolithography and etching operations, thereby forming a plurality of openings 121. Referring to FIG. 5, in some embodiments, the forming of the fin-like doped regions 120 includes doping the semiconductor substrate 102 through the openings 121. In some embodiments, an ion implantation 122 is performed, wherein an implant energy of the ion implantation 122 is less than that of the ion implantation 112 for forming the well 110. In some embodiments, the implant energy of the ion implantation 122 may be between approximately 60 keV and approximately 2500 keV, but the disclosure is not limited thereto. As shown in FIG. 5, the doped regions 120 are separated from each other by the semiconductor substrate 102, and are therefore referred to as the fin-like doped regions 120. The fin-like doped regions 120 are all coupled to the well 110. Further, the well 110 and the fin-like doped regions 120 include a same conductivity type. In some embodiments, the well 110 and the fin-like doped regions 120 together are referred to as a SPAD N-well 130.

In some embodiments, the ARC 107, the hard mask layer 105 and the pad oxide layer 103 may be removed after the forming of the fin-like doped regions 120.

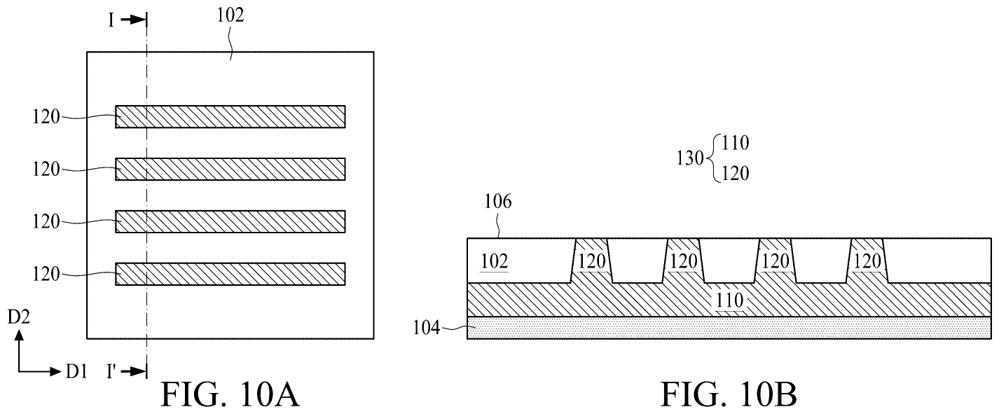

In some embodiments, the fin-like doped regions 120 may be periodically arranged. Please refer to FIGS. 10A and 10B, wherein FIG. 10A is a plan view of the semiconductor substrate 102 after the forming of the fin-like doped regions 120, and FIG. 10B is a cross-sectional view taken along a line I-I′ of FIG. 10A. As shown in FIGS. 10A and 10B, the fin-like doped regions 120 have a strip configuration extending in a direction D1 and arranged in a direction D2. The direction D2 is different from the direction D1. In some embodiments, the direction D1 and the direction D2 are perpendicular to each other, but the disclosure is not limited thereto.

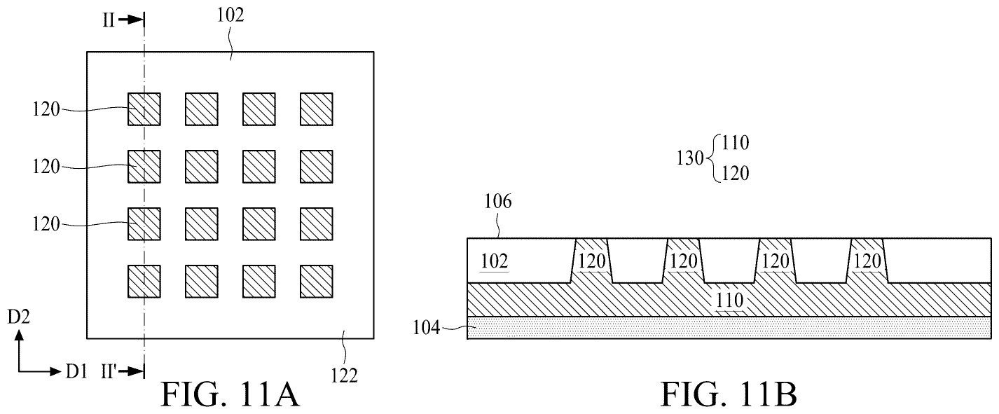

Please refer to FIGS. 11A and 11B, wherein FIG. 11A is a plan view of the semiconductor substrate 102 after the forming of the fin-like doped regions 120, and FIG. 11B is a cross-sectional view taken along a line II-II′ of FIG. 11A. As shown in FIGS. 11A and 11B, the fin-like doped regions 120 have an island configuration arranged in the direction D1 and the direction D2, and are separated from each other by the semiconductor substrate 102.

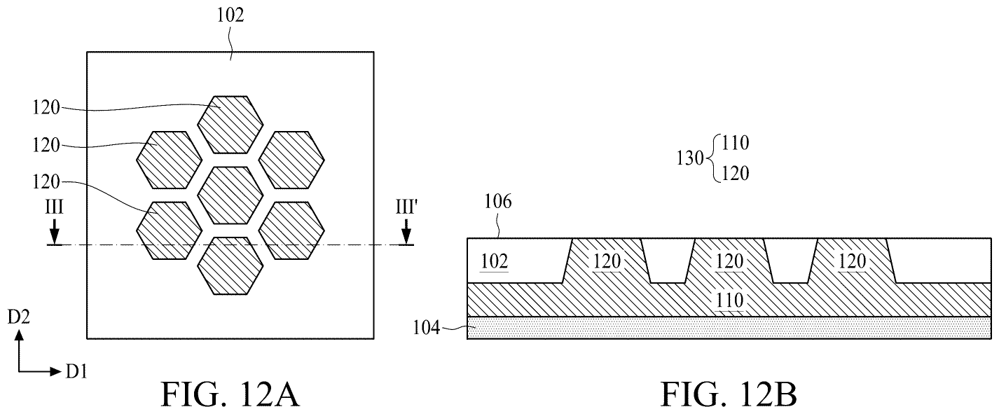

Please refer to FIGS. 12A to 12B, wherein FIG. 12A is a plan view of the semiconductor substrate 102 after the forming of the fin-like doped regions 120, and FIG. 12B is a cross-sectional view taken along a line III-III′ of FIG. 12A. As shown in FIGS. 12A and 12B, the fin-like doped regions 120 have a hexagonal-island configuration periodically arranged, and are separated from each other by the semiconductor substrate 102.

It should be noted that the configurations and arrangements of the fin-like doped regions 120 can be modified according to product design; therefore, the abovementioned strip configuration and island configuration are provided as examples only, and are not a limitation.

Additionally, in some embodiments, a well can be formed in a portion of the semiconductor substrate 102 at locations other than the fin-like doped regions 120. Such well may be an n-type well or a p-type well, depending on a type of an included field-effect transistor (FET) device, in application requiring the FET device. In some alternative embodiments, such well may be formed prior to the forming of the well 110 or after the forming of the fin-like doped regions 120, depending on process design.

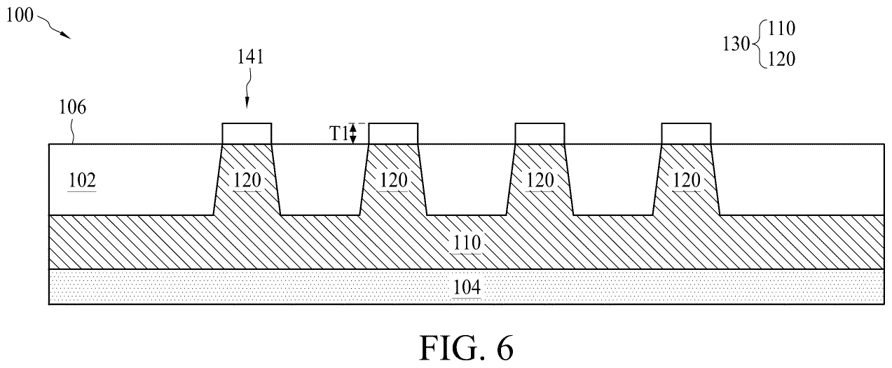

Referring to FIGS. 1, 6 and 7, in some embodiments, the method 10 includes an operation 14, in which a well 140 is formed in the semiconductor substrate 102 over the SPAD N-well 130 (i.e., the well 110 and the plurality of fin-like doped regions 120). In some embodiments, the operation 14 includes further operations. For example, referring to FIG. 6, a patterned mask layer 141 may be formed over the semiconductor substrate 102. As shown in FIG. 6, the patterned mask layer 141 may cover each of the fin-like doped regions 120. In some embodiments, the patterned mask layer 141 may be a dielectric layer such as, for example but not limited thereto, a silicon oxide layer. In some embodiments, the patterned mask layer 141 may be formed by a thermal operation. In other embodiments, the patterned mask layer 141 may be formed by a suitable deposition, such as chemical vapor deposition (CVD), physical vapor deposition (PVD), plasma-enhanced CVD (PECVD), high-density plasma CVD (HDP-CVD), or sub-atmospheric CVD (SACVD), but the disclosure is not limited thereto. In some embodiments, the dielectric layer is patterned using suitable photolithography and etching operations. A thickness T1 of the patterned mask layer 141 may be between approximately 90 micrometers (μm) and approximately 100 micrometers, but the disclosure is not limited thereto.

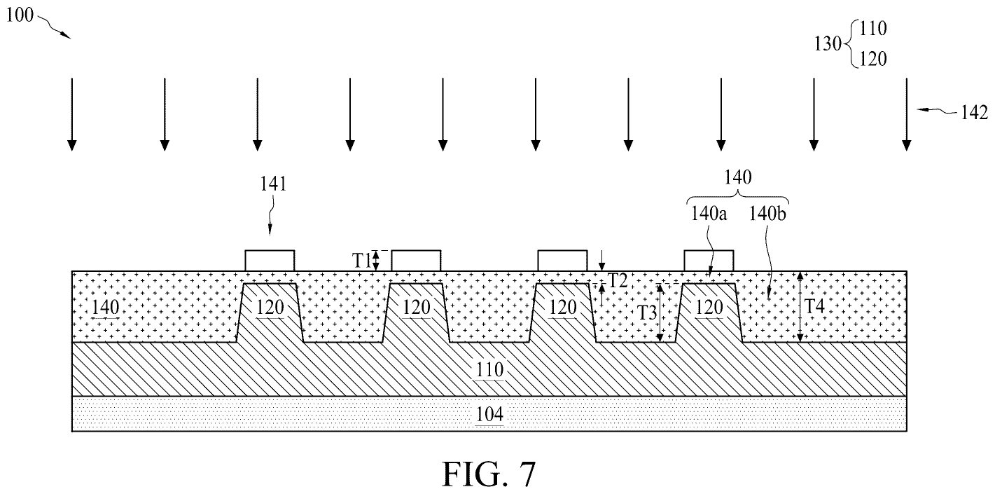

Referring to FIG. 7, the well 140 is formed over the well 110 and each of the fin-like doped regions 120. In some embodiments, the well 140 includes dopants having a conductivity type complementary to that of the dopants in the well 104, the well 110 and the fin-like doped regions 120. For example, the well 140 may include p-type dopants. In such embodiments, the well 140 may be referred to as a SPAD P-well. In some embodiments, the forming of the well 140 includes doping the semiconductor substrate 102 and the fin-like doped regions 120. In some embodiments, the doping includes an ion implantation 142. In some embodiments, an implant energy of the ion implantation 142 is less than the implant energy of the ion implantation 112. For example but not limited thereto, the implant energy of the ion implantation 142 is between approximately 60 keV and approximately 2500 keV. Because the implant energy of the ion implantation 142 is less than the implant energy of the ion implantation 112, a depth of the well 140 is less than that of the well 110. In some embodiments, the well 140 may be formed over the well 110, as shown in FIG. 7. Additionally, the well 140 is in contact with the well 110, but is separated from the well 104 by the well 110.

Still referring to FIG. 7, in some embodiments, the well 140 may be defined to have a first portion 140a formed over each of the fin-like doped regions 120, and a second portion 140b formed over the well 110 where the fin-like doped regions 120 are absent. In some embodiments, a portion of each fin-like doped region 120 is doped through the patterned mask layer 141. In such embodiments, the thickness T1 of the patterned mask layer 141 helps to control a thickness T2 of the first portion 140a of the well 140 over each fin-like doped region 120. For example, the thinner the patterned mask layer 141 is, the thicker the first portion 140a is. Further, the thickness T2 of the first portion 140a of the well 140 determines a thickness T3 of the fin-like doped region 120 after the forming of the well 140. For example, the thicker the first portion 140a is, the thinner the fin-like doped region 120 is. In some embodiments, the thickness T2 of the first portion 140a of the well 140 is less than the thickness T3 of the fin-like doped region 120. Further, the second portion 140b of the well 140 has a thickness T4, and the thickness T4 of the second portion 140b is greater than the thickness T2 of the first portion 140a. In other words, the well 140 has inconsistent thicknesses T2 and T4. In some embodiments, the thickness T4 of the second portion 140b may be equal to a sum of the thickness T2 of the first portion of the well 140 and the thickness T3 of the fin-like doped region 120.

As mentioned above, the thickness of the patterned mask layer 141 is between approximately 90 μm and approximately 100 μm. In some comparative approaches, the thickness T1 of the patterned mask layer 141 is less than 90 μm, and the thickness T2 of the first portion 140a may be equal to or greater than the thickness T3 of the fin-like doped region 120, resulting in a reduced ability of the device to trigger of the avalanche effect. In some comparative approaches, when the thickness T1 of the patterned mask layer 141 is greater than 100 μm, the ions cannot penetrate the patterned mask layer 141, resulting in formation of an incomplete first portion 140a and a defective or failed device.

The patterned mask layer 141 is removed after the forming of the well 140.

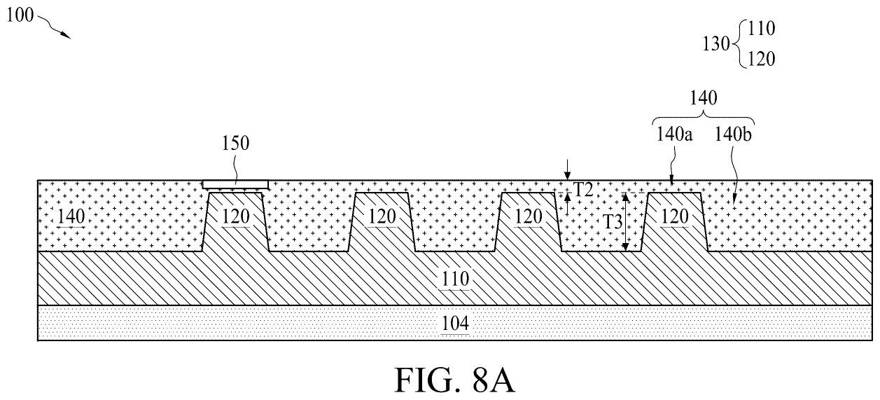

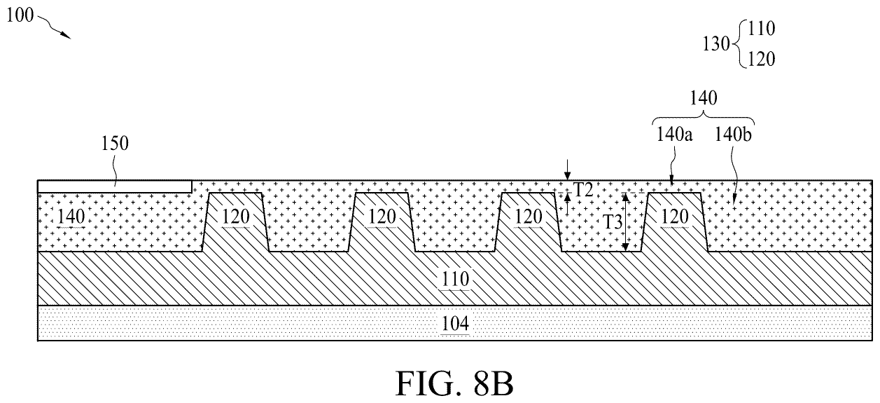

Please refer to FIGS. 8A and 8B, which are schematic drawings illustrating a stage subsequent to the removing of the patterned mask layer 141 in accordance with various embodiments. In some embodiments, a doped region 150 may be formed in one of the first portion 140a of the well 140 as shown in FIG. 8A, or formed in a portion of the second portion 140b of the well 140 as shown in FIG. 8B. In some embodiments, the forming of the doped region 150 includes doping the one of the first portions 140a or doping the portion of the second portion 140b. The doped region 150 and the well 140 include a same conductivity type, i.e., the p-type. A dopant concentration of the doped region 150 is greater than a dopant concentration of the well 140. In some embodiments, the doped region 150 is referred to as a heavily-doped region and is formed to provide an adequate ohmic contact with a connecting structure.

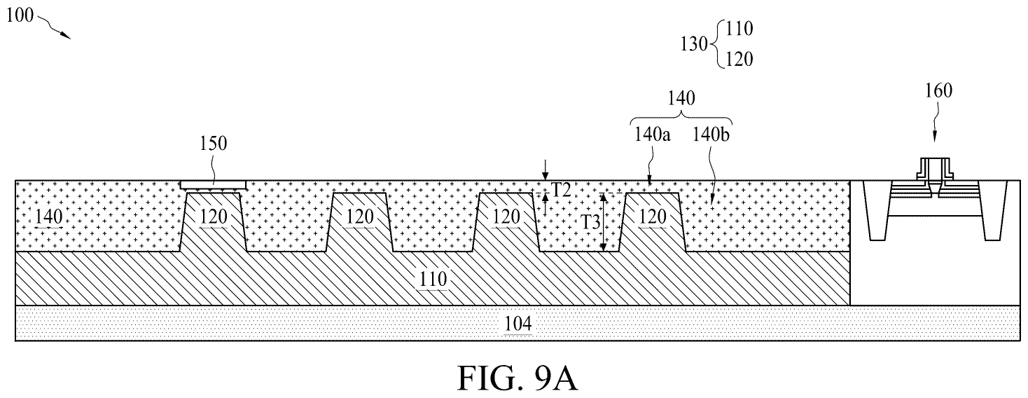

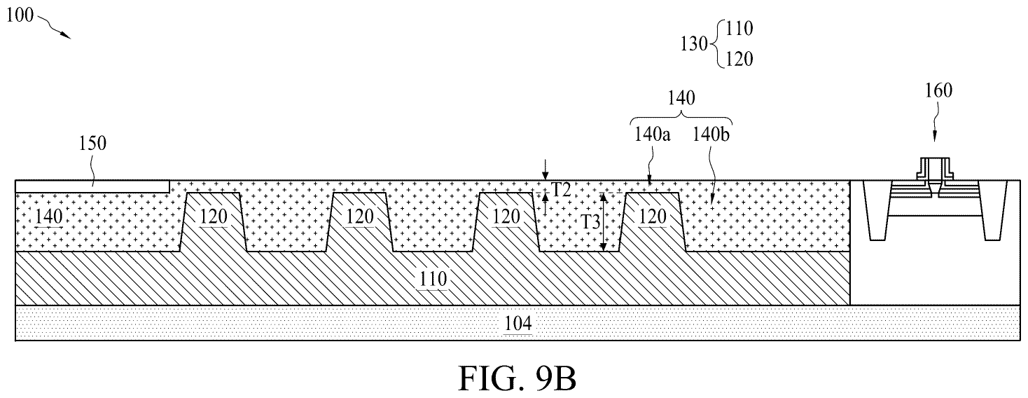

Referring to FIGS. 9A and 9B, in some embodiments, a FET device 160 may be formed over a semiconductor substrate 102 but the disclosure is not limited thereto. In some embodiments, when the FET device 160 is a FinFET device that includes at least a fin structure where a channel is to be formed, a dimension of the fin structure is less than a dimension of a fin-like doped region 120, though not shown.

Still referring to FIGS. 9A and 9B, in accordance with some embodiments, a SPAD sensor 100 is provided. The SPAD sensor 100 includes a well 104, a SPAD N-well 130 that includes a well 110 and a plurality of fin-like doped regions 120, a SPAD P-well 140, and a doped region 150. The well 104 is disposed in the semiconductor substrate 102 and under the SPAD N-well 130. The well 110 of the SPAD N-well 130 is formed under the fin-like doped regions 120 in the semiconductor substrate 102. As shown in FIGS. 9A and 9B, in some embodiments, the well 110 may be in contact with the well 104. The SPAD P-well 140 has first portions 140a over the fin-like doped regions 120 and second portions 140b over the well 110 where the fin-like doped regions 120 are absent. A bottom of the first portion 140a is in contact with the fin-like doped region 120, and a bottom of the second portion 140b is in contact with the well 110. An interface between the SPAD P-well 140 and the SPAD N-well 130 has a non-planar or wavy configuration, and such interface provides a p-n junction where photo-generated carriers are formed. As shown in FIGS. 9A and 9B, an area of the p-n junction, which is a multiplication junction region, is increased due to the wavy or non-planar configuration of the interface. Accordingly, a quantity of the photo-generated carriers generated in the p-n junction is increased, and thus performance of the SPAD sensor 100 is improved.

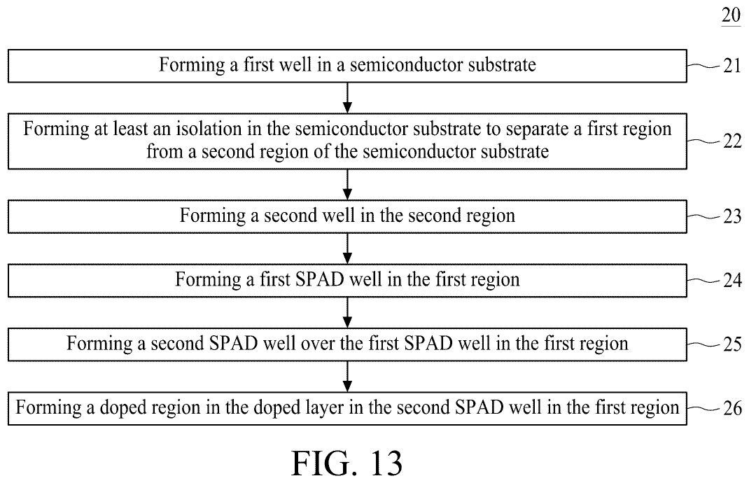

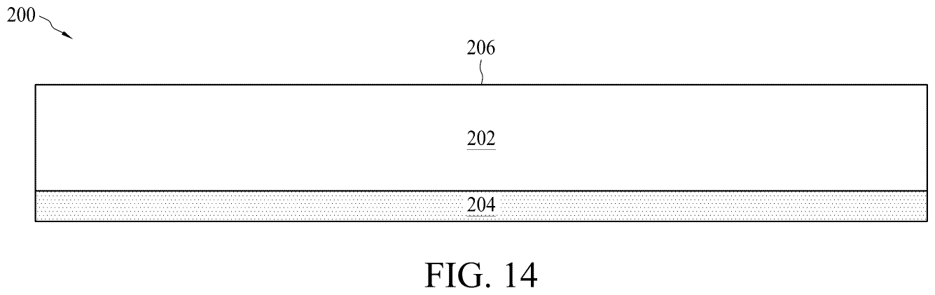

Please refer to FIG. 13, which is a flowchart representing a method 20 for forming a semiconductor structure 200 including a SPAD sensor 100 in accordance with aspects of the present disclosure. Persons having ordinary skill in the art will understand that, in some embodiments, additional operations may be performed before, during or after the method 20, and that some of the operations described may be replaced or eliminated in some embodiments, of the method 20. FIGS. 14 to 24B are schematic drawings illustrating the method 20 of forming the semiconductor structure 200 including the SPAD sensor 100 at various fabrication stages in accordance with some embodiments of the present disclosure.

Referring to FIGS. 13 and 14, in some embodiments, the method 20 includes an operation 21, in which a well 204 is formed in a semiconductor substrate 202. In some embodiments, the operation 21 is similar to operation 11. The semiconductor substrate 202 may be similar to the semiconductor substrate 102; therefore, repeated descriptions of details are omitted for brevity. The well 204 may include dopants of a first conductivity type, such as an n type. In such embodiments, the well 204 may also be referred to as a deep n-well (DNW). As shown in FIG. 14, the well 204 is separated from a surface 206 of the semiconductor substrate 202.

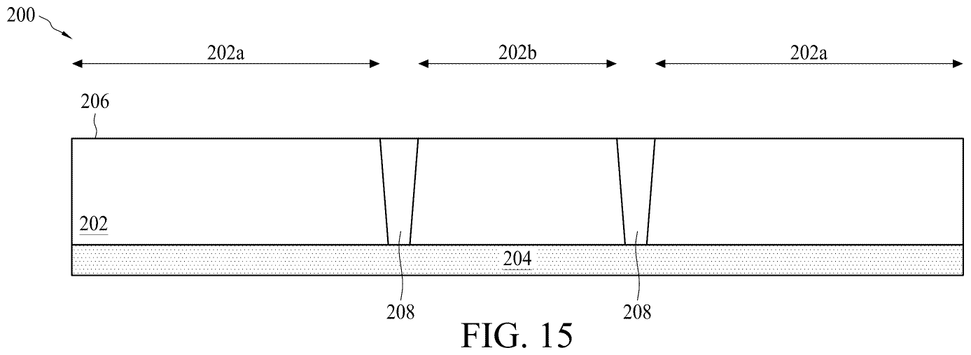

Referring to FIGS. 13 and 15, in some embodiments, the method 20 includes an operation 22, in which at least an isolation 208 is formed to define and separate a first region 202a from a second region 202b in the semiconductor substrate 202. In some embodiments, a bottom surface of the isolation 208 may be in contact with the well 204, but the disclosure is not limited thereto. In some embodiments, the isolation 208 is formed by etching recesses (not shown) in the semiconductor substrate 202 using a photolithography process, and filling the recesses with one or more dielectric materials. In some embodiments, the recesses are formed by forming a photoresist layer (not shown) over the semiconductor substrate 202, lithographically patterning the photoresist layer, and transferring the pattern into an upper portion of the semiconductor substrate 202 by an anisotropic etching operation, such as reactive ion etching (RIE) or plasma etching. The dielectric material is deposited by CVD or PVD. Excess dielectric material is then removed from above the surface 206 of the semiconductor substrate 202, for example, by chemical mechanical planarization (CMP). After the planarization, a top surface of the isolation 208 is aligned (i.e., coplanar) with the surface 206 of the semiconductor substrate 202. In some embodiments, the isolation 208 may include a field oxide formed by a thermal oxidation.

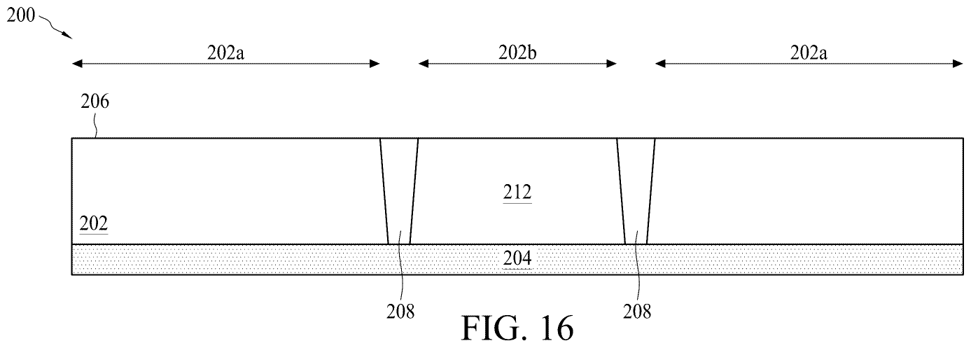

Referring to FIGS. 13 and 16, in some embodiments, the method 20 includes an operation 23, in which a well 212 is formed in the second region 202b. In some embodiments, the forming of the well 212 includes doping a portion of the semiconductor substrate 202 in the second region 202b. The first region 202a may be defined to accommodate the SPAD sensor 100. In some embodiments, the second region 202b may be defined to accommodate a logic device (not shown) or an input/output device (not shown), depending on product design. In some embodiments, the well 212 is a high-voltage N-well (HVNW), but the disclosure is not limited thereto.

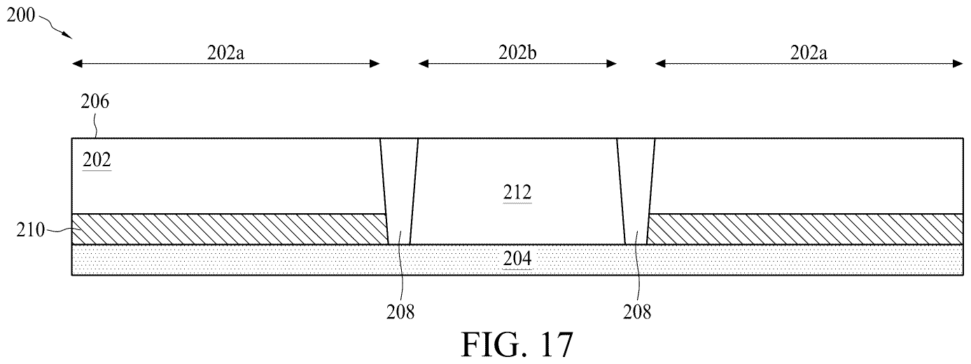

Referring to FIGS. 13 and 17, in some embodiments, the method 20 includes an operation 24, in which a first SPAD well 230 is formed in the first region 202a. In some embodiments, the operation 24 is similar to operation 12 and operation 13. For example, a well 210 may be formed in the semiconductor substrate 202 in the first region 202a. As shown in FIG. 17, the well 210 is formed over the well 204. In some embodiments, the forming of the well 210 may be similar to the forming of the well 110; therefore, repeated descriptions of details are omitted for brevity. The well 210 may include dopants of a first conductivity type, such as an n type.

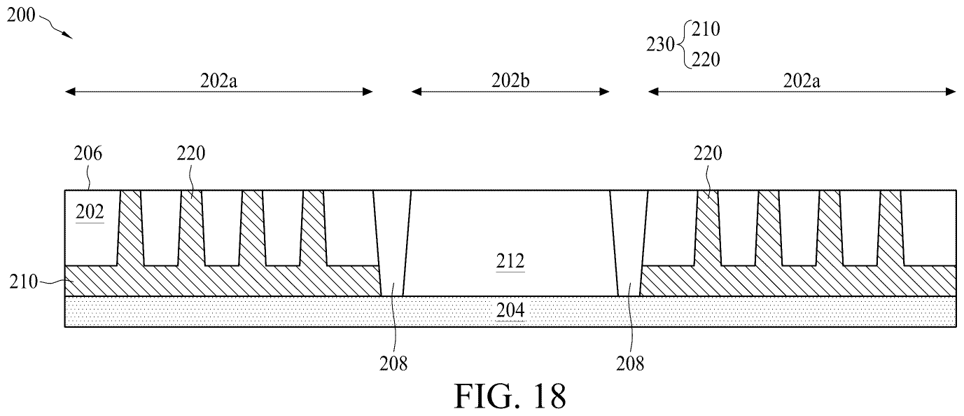

Referring to FIGS. 13 and 18, in some embodiments, operation 24 further includes forming a plurality of fin-like doped regions 220 in the first region 202a. The fin-like doped regions 220 are separated from each other by the semiconductor substrate 202, as shown in FIG. 18. In some embodiments, the forming of the fin-like doped regions 220 may be similar to the forming of the fin-like doped region 120; therefore, such details are omitted for brevity. Further, configuration and arrangement of the fin-like doped regions 220 may be similar to those described above and shown in FIGS. 10A to 12B; therefore, such details are also omitted for brevity.

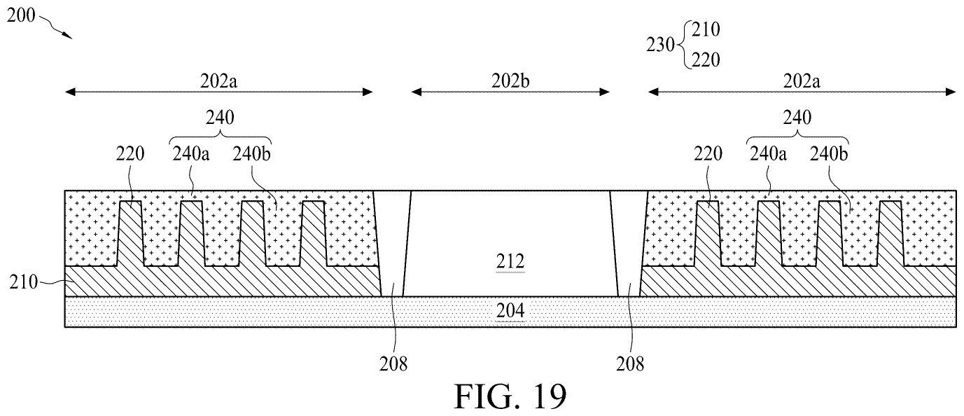

Referring to FIGS. 13 and 19, in some embodiments, the method 20 includes an operation 25, in which a second SPAD well 240 is formed over the first SPAD well 230 in the first region 202a. In some embodiments, the operation 25 is similar to the operation 14. In such embodiments, the operation 25 includes forming a patterned mask layer (not shown) over the semiconductor substrate 202. The patterned mask layer may cover and protect the fin-like doped regions 220 in the first region 202a and the well 212 in the second region 202b during the forming of the second SPAD well 240. The forming of the second SPAD well 240 includes performing an ion implantation. The ion implantation for forming the second SPAD well 240 may be similar to that used to form the SPAD P-well 140; therefore, details thereof are omitted for brevity. As mentioned above, the second SPAD well 240 includes dopants having a conductivity type complementary to that of the dopants in first SPAD well 230. For example, the second SPAD well 240 may include p-type dopants.

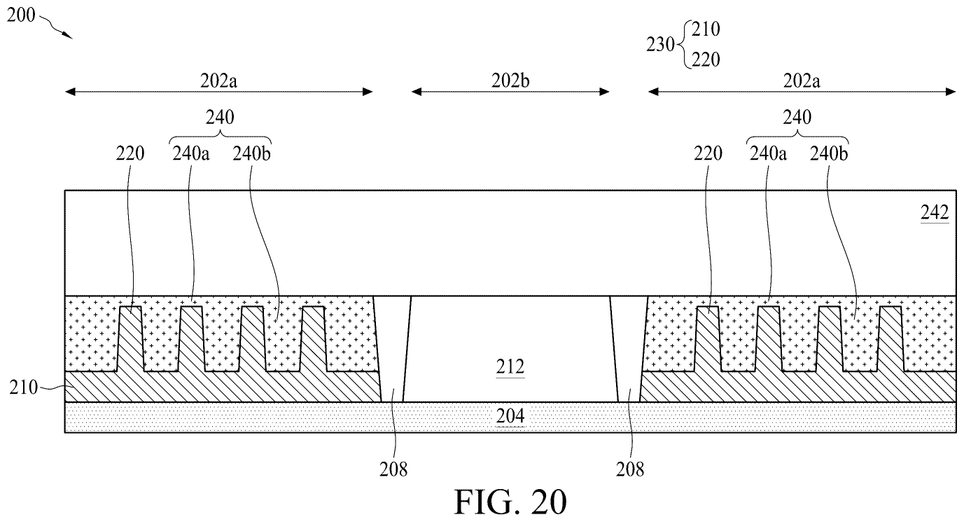

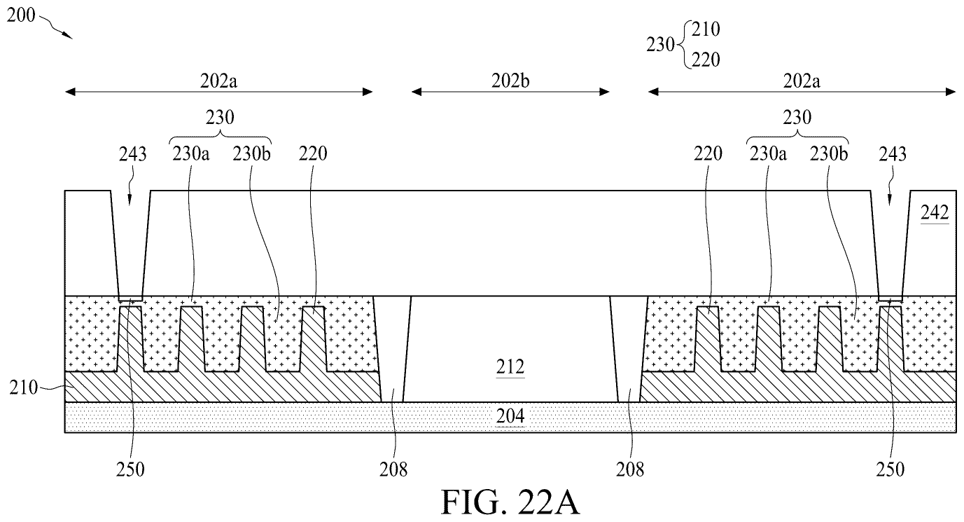

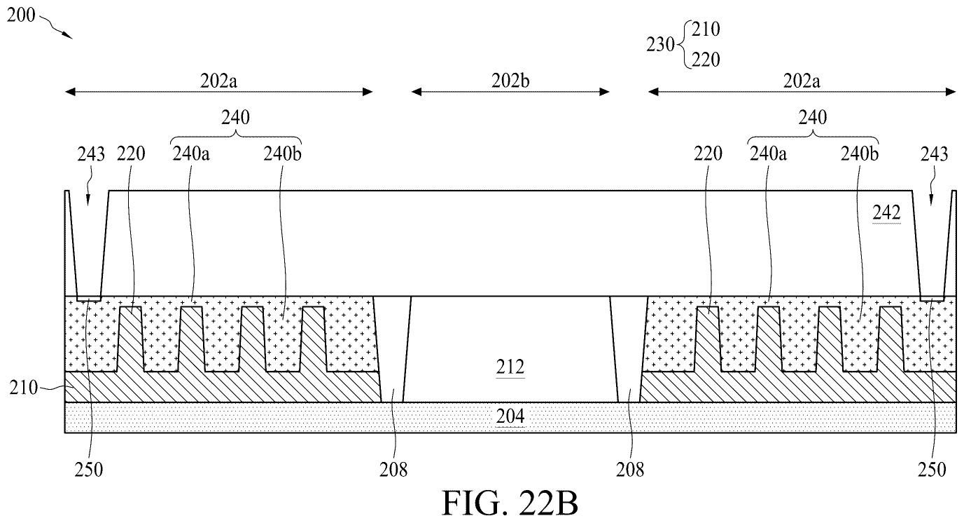

Referring to FIGS. 13, 22A and 22B, in some embodiments, the method 20 includes an operation 26, in which a doped region 250 is formed in the second SPAD well 240 in the first region 202a. In some embodiments, the forming of the doped region 250 includes further operations. For example, referring to FIG. 20, in some embodiments, a dielectric structure 242 is formed over the semiconductor substrate 202 in both the first region 202a and the second region 202b. In some embodiments, the dielectric structure 242 includes an inter-layer dielectric (ILD) layer. In some embodiments, the dielectric structure 242 includes an ILD layer and a contact etch stop layer (CESL), but the disclosure is not limited thereto. In some embodiments, the dielectric structure 242 is deposited using, for example but not limited thereto, CVD, PVD, PECVD or spin-on coating. In some embodiments, the dielectric structure 242 includes material having a low dielectric constant (low-k), such as a dielectric constant less than about 3.9. In some embodiments, the dielectric constant (also referred to as a k value) is less than about 3.0, or less than about 2.5. In some embodiments, the dielectric structure 242 includes spin-on-glass (SOG), fluoride-doped silicate glass (FSG), carbon doped silicon oxide, black Diamond® (Applied Materials of Santa Clara, Calif.), Xerogel, Acrogel, amorphous fluorinated carbon, parylene, BCB (bis-benzocyclobutenes), SiLK (Dow Chemical, Midland, Mich.), polyimide, and/or other suitable materials.

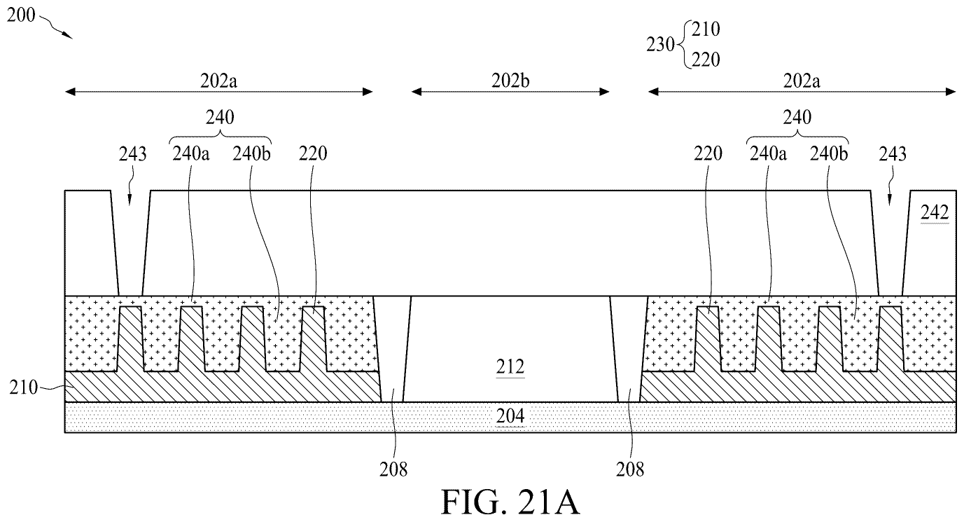

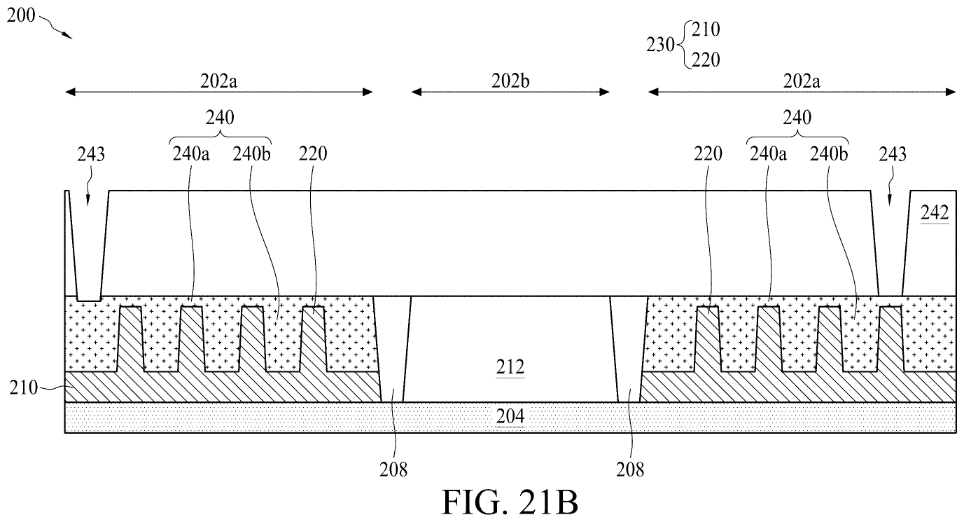

Referring to FIGS. 21A and 21B, in some embodiments, an opening 243 is formed in the dielectric structure 242. In some embodiments, the forming of the opening 243 includes patterning the dielectric structure 242 using suitable photolithography and etching operations. Referring to FIG. 21A, in some embodiments, the opening 243 is formed in the dielectric structure 242 to expose a portion of the first portion 240a of the second SPAD well 240. In other embodiments, as shown in FIG. 21B, the opening 243 is formed to expose a portion of the second portion 240b of the second SPAD well 240.

In some embodiments, the doped region 250 is formed in a bottom of the opening 243. In some embodiments, the forming of the doped region 250 includes doping the first portion 240a of the second SPAD well 240 exposed through the bottom of the opening 243, as shown in FIG. 22A. In such embodiments, the doped region 250 is separated from the fin-like doped region 220 by the second SPAD well 240. Referring to FIG. 22B, in some embodiments, the forming of the doped region 250 includes doping the second portion 240b of the second SPAD well 240 exposed through the bottom of the opening 243. The doped region 250 and the second SPAD well 240 include a same conductivity type, i.e., the p-type. A dopant concentration of the doped region 250 is greater than a dopant concentration of the second SPAD well 240. In some embodiments, the doped region 250 is referred to as a heavily-doped region that is formed to provide an adequate ohmic contact with a connecting structure.

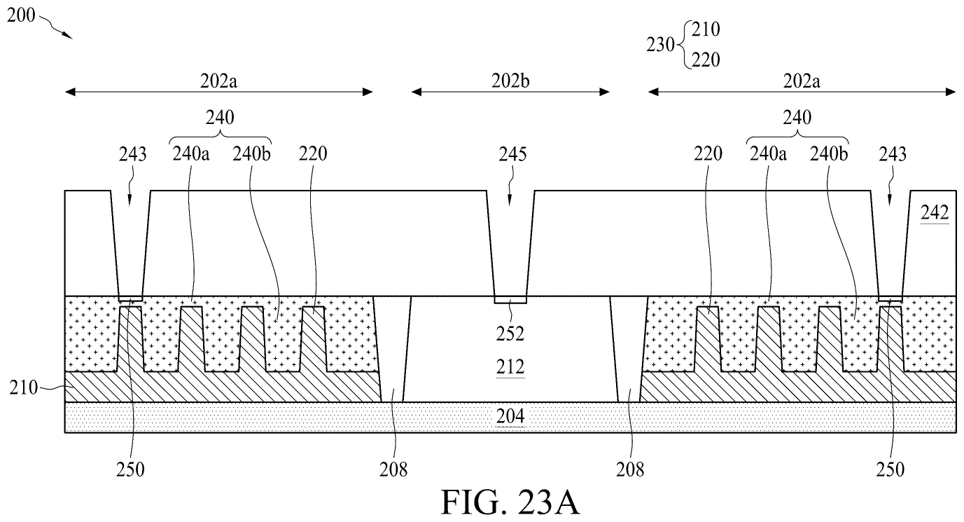

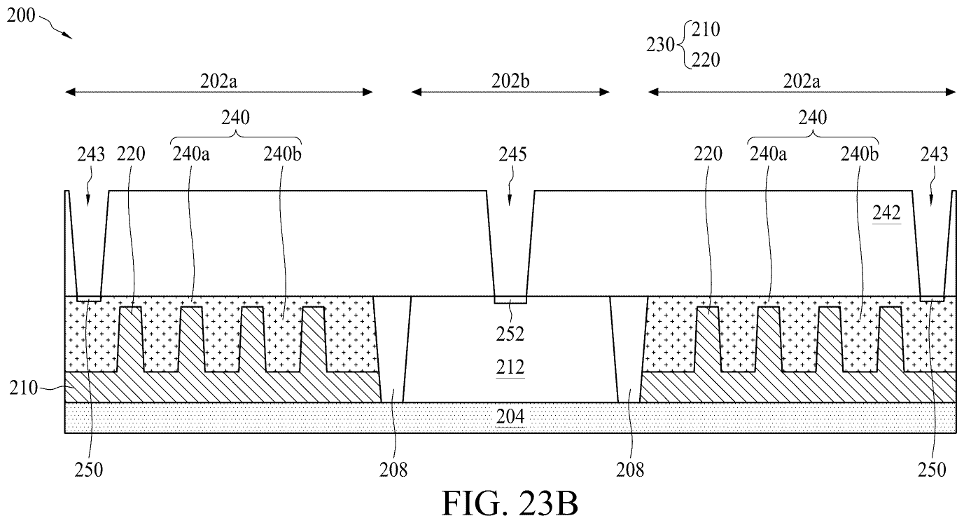

Referring to FIGS. 23A and 23B, in some embodiments, another opening 245 is formed in the dielectric structure 242 in the second region 202b. The opening 245 may expose a portion of the well 212 in the second region 202b. Further, another doped region 252 is formed over the portion of the well 212 exposed through a bottom of the opening 245. In some embodiments, the forming of the doped region 252 includes doping a portion of the semiconductor substrate 202 in the second region 202b that is exposed through the opening 245. In some embodiments, the doped region 252 and the well 212 include a same conductivity type, i.e., the n-type. A dopant concentration of the doped region 252 is greater than the dopant concentration of the well 212. In some embodiments, the doped region 252 is referred to as a heavily-doped region that is formed to provide an adequate ohmic contact with a connecting structure. In some embodiments, the forming of the opening 245 and the forming of the doped region 252 are performed after the forming of the opening 243 and the doped region 250, as shown in FIGS. 22A and 22B, but the disclosure is not limited thereto. In some alternative embodiments, the opening 245 and the doped region 252 may be formed before the forming of the opening 243 and the doped region 250, though not shown.

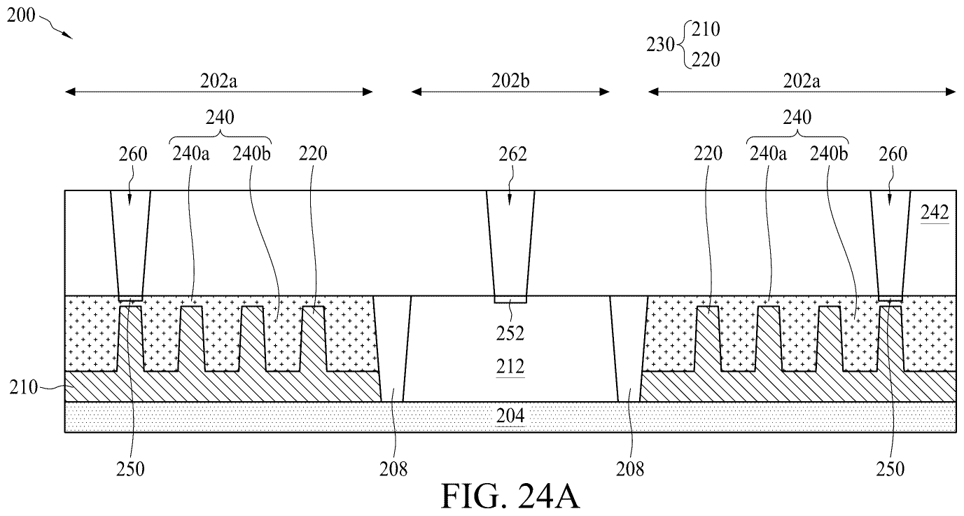

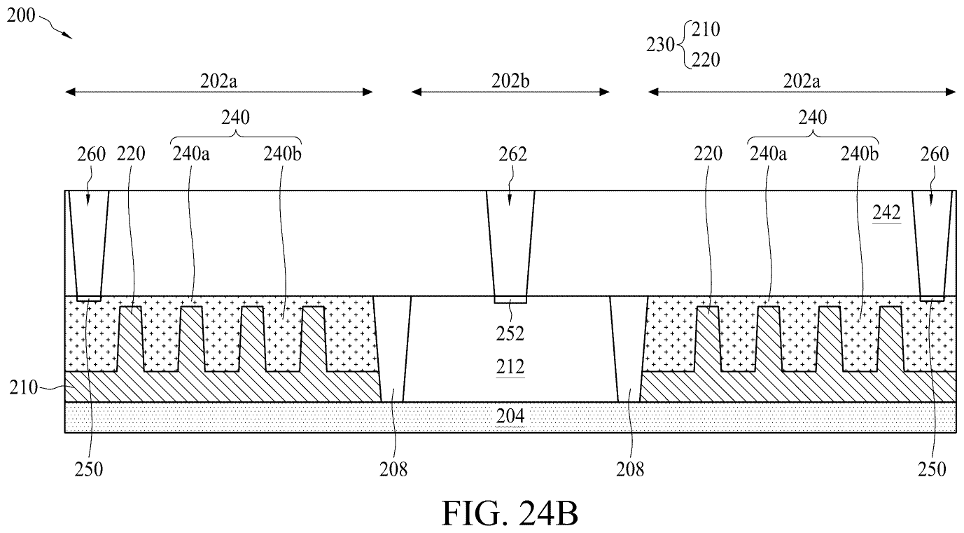

Referring to FIGS. 24A and 24B, in some embodiments, the method 20 further include forming a connecting structure 260 in the first region 202a, and a connecting structure 262 in the second region 202b. As shown in FIG. 24A, in some embodiments, the connecting structure 260 is coupled to the doped region 250 formed over the first portion 240a of the second SPAD well 240 over one of the fin-like doped regions 220 in the first region 202a, and the connecting structure 262 is coupled to the doped region 252 formed over the well 212 in the second region 202b. As shown in FIG. 24B, in some embodiments, the connecting structure 260 is coupled to the doped region 250 formed over the second portion 240b of the second SPAD well 240 in the first region 202a, and the connecting structure 262 is coupled to the doped region 252 formed over the well 212 in the second region 202b. Accordingly, the connecting structure 260 forms an ohmic contact with the corresponding doped region 250, and the connecting structure 262 forms an ohmic contact with the corresponding doped region 252. The connecting structures 260 and 262 may be referred to as contact plugs that connect the SPAD sensor 100 to overlying metallization layers (not shown). In some embodiments, the connecting structures 260 and 262 include a conductive material such as, for example, copper, tungsten, aluminum, or an alloy thereof. In some embodiments, the connecting structures 260 and 262 also include a barrier/adhesion liner (not shown) to prevent diffusion and to provide better adhesion for the connecting structures 260 and 262. In some embodiments, the barrier/adhesion liner includes titanium nitride (TiN). Accordingly, the semiconductor structure 200 including the SPAD sensor 100 is obtained.

Accordingly, the present disclosure provides a SPAD sensor having a plurality of fin-like p-n junctions. In some embodiments, the fin-like p-n junctions, which are formed by doping, have a wavy or non-planar configuration. Accordingly, an area of the fin-like p-n junction is increased. As a result, a quantity of photo-generated carriers generated in the fin-like p-n junction per unit area is increased compared to a quantity of photo-generated carriers in a comparative SPAD sensor having the p-n junction formed in a planar surface. Accordingly, efficiency of the SPAD sensor is improved, and resolution for application of machine vision is improved.

In accordance with one embodiment of the present disclosure, a method of forming a sensor is provided. The method includes following operations. A semiconductor substrate is received. The semiconductor substrate includes a first well formed therein. A second well is formed over the first well in the semiconductor substrate. A plurality of fin-like doped regions are formed over and coupled to the second well. A third well is formed over the second well and the plurality of fin-like doped regions.

In accordance with one embodiment of the present disclosure, a method for forming a semiconductor structure is provided. The method includes following operations. A first well is formed in a semiconductor substrate. At least an isolation is formed in the semiconductor substrate. The isolation separates a first region of the semiconductor substrate from a second region of the semiconductor substrate. A second well is formed in the second region. A first SPAD well is formed in the first region. A second SPAD well is formed over the first SPAD well in the first region. A first doped region is formed in the second SPAD well in the first region. An interface between the first SPAD well and the second SPAD well has a non-planar configuration.

In accordance with one embodiment of the present disclosure, a semiconductor structure is provided. The semiconductor structure includes a first well in a semiconductor substrate, a plurality of fin-like doped regions over and coupled to the first well in the semiconductor substrate, and a second well over the first well and the plurality of fin-like doped regions in the semiconductor substrate. The first well and the plurality of fin-like doped regions comprise a first conductivity type, and the second well comprises a second conductivity type complementary to the first conductivity type. A first interface is formed between the second well and the first well, a second interface is formed between the second well and the plurality of fin-like doped regions, and each of the first interface and the second interface has a non-planar configuration.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a sensor, comprising:
receiving a semiconductor substrate comprising a first well formed therein;
forming a second well over the first well in the semiconductor substrate;
forming a plurality of fin-like doped regions over and coupled to the second well; and
forming a third well over the second well and the plurality of fin-like doped regions.

2. The method of claim 1, wherein the first well, the second well and the plurality of fin-like doped regions have a first conductivity type.

3. The method of claim 2, wherein the third well includes a second conductivity type complementary to the first conductivity type.

4. The method of claim 1, further comprising forming a patterned mask layer over the plurality of fin-like doped regions prior to the forming of the third well.

5. The method of claim 1, wherein the third well comprises:
a first portion over each of the plurality of fin-like doped regions; and
a second portion over the second well where the fin-like doped regions are absent.

6. The method of claim 5, wherein a thickness of the first portion is less than a thickness of each fin-like doped region.

7. The method of claim 5, further comprising forming a doped region in the first portion or the second portion of the third well.

8. A method for forming a semiconductor structure, comprising:
forming a first well in a semiconductor substrate;
forming at least an isolation in the semiconductor substrate to separate a first region from a second region of the semiconductor substrate;
forming a second well in the second region;
forming a first SPAD well in the first region;
forming a second SPAD well over the first SPAD well in the first region; and
forming a first doped region in the second SPAD well in the first region,
wherein an interface between the first SPAD well and the second SPAD well has a non-planar configuration.

9. The method of claim 8, wherein the first well, the second well and the first SPAD well comprise a first conductivity type.

10. The method of claim 9, wherein the second SPAD well and the first doped region comprise a second conductivity type complementary to the first conductivity type.

11. The method of claim 10, wherein a dopant concentration of the first doped region is greater than a dopant concentration of the second SPAD well.

12. The method of claim 8, wherein the forming of the first doped region further comprises:
forming a dielectric structure over the semiconductor substrate;
forming an opening exposing a portion of the second SPAD well, wherein the doped region is formed in the portion of the second SPAD well exposed through the opening.

13. The method of claim 12, further comprising forming a connecting structure in the opening, wherein the connecting structure is coupled to the first doped region.

14. The method of claim 8, further comprising:
forming second doped region in the first well in the second region; and
forming a connecting structure coupled to the second doped region,
wherein the first well and the second doped region comprise a same conductivity type.

15. A semiconductor structure comprising:
a first well in a semiconductor substrate;
a plurality of fin-like doped regions over and coupled to the first well in the semiconductor substrate; and
a second well over the first well and the plurality of fin-like doped regions in the semiconductor substrate,
wherein the first well and the plurality of fin-like doped regions comprise a first conductivity type, and the second well comprises a second conductivity type complementary to the first conductivity type, and
wherein a first interface is formed between the second well and the first well, a second interface is formed between the second well and the plurality of fin-like doped regions, and each of the first interface and the second interface has a non-planar configuration.

16. The semiconductor structure of claim 15, further comprising a deep well in the semiconductor substrate, wherein the first well, the plurality of fin-like doped regions and the second well are formed over the deep well.

17. The semiconductor structure of claim 15, wherein the second well comprises:
a first portion over each of the plurality of fin-like doped regions; and
a second portion over the first well wherein the fin-like doped regions are absent.

18. The semiconductor structure of claim 17, wherein a thickness of the first portion of the second well is less than a thickness of each of the plurality of fin-like doped regions.

19. The semiconductor structure of claim 17, further comprising a doped region disposed in the first portion of the second well or the second portion of the second well.

20. The semiconductor structure of claim 19, further comprising a connecting structure coupled to the doped region.
